(19) United States
(12) Patent Application Publication
(10) Pub. No.: US 2026/0056270 A1
(43) Pub. Date: Feb. 26, 2026

(54) SYSTEM AND METHOD FOR SUPPRESSING TECHNICAL NOISE IN ABSORPTION-BASED LASER THRESHOLD MAGNETOMETRY

(71) Applicant: Government of the United States as represented by the Secretary of the Air Force, Wright-Patterson AFB, OH (US)

(72) Inventors: Robert Bedford, Beavercreek, OH (US); Gary Sevison, Washington Township, OH (US); Michael Slocum, Dayton, OH (US)

(21) Appl. No.: 19/293,228

(22) Filed: Aug. 7, 2025

Related U.S. Application Data
(60) Provisional application No. 63/685,526, filed on Aug. 21, 2024.

(51) Int. Cl. G01R 33/26; G01R 33/032

(52) U.S. Cl. CPC G01R 33/26; G01R 33/032

(57) ABSTRACT

A method of accounting for signal noise in a hybrid laser system is described. The hybrid laser system includes a high reflectivity mirror, a nitrogen-vacancy center diamond, a microwave antenna, a dichroic mirror, a half-vertical cavity surface emitting laser (VCSEL), a birefringent filter, an etalon, an output coupler, and a photodiode. The method includes: measuring a shift in a left-hand side frequency as related to an optically detected magnetic resonance (ODMR) frequency peak of an ODMR signal; measuring a shift in a right-hand side frequency as related to the ODMR frequency peak; normalizing the shift in the left-hand side frequency; normalizing the shift in the right-hand side frequency; and comparing the shift in the left-hand side frequency to the shift in the right-hand side frequency to determine a technical noise associated with the ODMR signal.

### CROSS REFERENCE TO RELATED APPLICATIONS

Pursuant to 37 C.F.R. § 1.78(a)(4), this application claims the benefit of and priority to prior filed co-pending Provisional Application No. 63/685,526, filed Aug. 21, 2024, which is expressly incorporated herein by reference in its entirety.

### RIGHTS OF THE GOVERNMENT

The invention described herein may be manufactured and used by or for the Government of the United States for all governmental purposes without the payment of any royalty.

### FIELD OF THE INVENTION

The present invention relates generally to magnetometry and, more particularly, to magnetometry using NV center diamonds and laser systems.

### BACKGROUND OF THE INVENTION

Nitrogen-vacancy (NV) centers have considerable promise for use as magnetometers, however miniaturization is limited by inefficient collection of the photoluminescence used to read out magnetic fields. Laser threshold magnetometry (LTM) enables efficient signal collection, providing a path towards compact high sensitivity magnetometry. Currently, demonstrations reveal technical noise associated with mechanical vibrations, component thermal fluctuations thermal atmospheric flows, and pump noise. These various noises all lead to sensitivities that are order(s) of magnitude higher than the photon shot-noise limit which defines the lowest limit of possible sensitivity for a given sensor. Therefore the ability to separate signal variations which allow for separation of signals of interest (resulting from magnetic field variations) from laser noise would be beneficial.

### SUMMARY OF THE INVENTION

The present invention overcomes one or more of the foregoing problems and other shortcomings, drawbacks, and challenges of optically-detected magnetic resonance (ODMR) readout of NV diamond magnetometry. While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention, a method of accounting for signal noise in a hybrid laser system is described. The hybrid laser system includes a high reflectivity mirror, a nitrogen-vacancy center diamond, a microwave antenna, a dichroic mirror, a half-vertical cavity surface emitting laser (VCSEL), a birefringent filter, an etalon, an output coupler, and a photodiode. The method includes: measuring a shift in a left-hand side frequency as related to an optically detected magnetic resonance (ODMR) frequency peak of an ODMR signal; measuring a shift in a right-hand side frequency as related to the ODMR frequency peak; normalizing the shift in the left-hand side frequency; normalizing the shift in the right-hand side frequency; and comparing the shift in the left-hand side frequency to the shift in the right-hand side frequency to determine a technical noise associated with the ODMR signal.

In another embodiment, a method of retrieving signals at two radiofrequencies on either side of a peak frequency includes steps of: modulate a left-hand side frequency at a left-hand low lock-in modulation frequency and retrieve the modulated left-hand side frequency using a first lock-in amplifier; modulate a right-hand side frequency at a right-hand low lock-in modulation frequency and retrieve the modulated right-hand side frequency using a second lock-in amplifier; and subtract the modulated left-hand side frequency from the right-hand side frequency using a single lock-in amplifier using a signal modulation frequency to the left-hand side frequency and the right-hand side frequency based on the left-hand side frequency and the right-hand side frequency being 180 degrees out of phase as compared to one another.

In yet another embodiment, a method of suppressing noise and accounting for thermal drift in a hybrid laser system includes: monitoring a first frequency peak and a second frequency peak on either of: 1) a low-frequency side or, 2) a high-frequency side of an average frequency peak; modulating the first frequency peak at a first low lock-in frequency and retrieve the modulated first frequency peak with a first lock-in amplifier; modulating the second frequency peak at a second low lock-in frequency and retrieve the modulated second frequency peak with a second lock-in amplifier; subtracting the modulated, retrieved second frequency peak from the modulated, retrieved first frequency peak to account for thermal drift in the hybrid laser system.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 shows a schematic of relevant energy levels of a nitrogen vacancy (NV) diamond and a laser system for reading magnetometric signals from using the NV diamond.

FIG. 2 shows an optically-detected magnetic resonance (ODMR) spectrum of spin down transitions.

FIG. 3 shows a contrast as a function of normalized 808 nm pump power when probing all transitions with no bias field. The inset plot shows the ODMR signal (recorded by lock-in amplifier (LIA)) and total output power (recorded by DMM).

FIG. 4 shows an ODMR frequency (GHz) v. a laser signal level for multiple frequencies.

FIG. 5 shows an ODMR frequency (GHz) v. a laser signal level for multiple frequencies.

FIG. 6 shows a shift in an ODMR frequency (GHz) based on random intensity noise (RIN), thermal shift, magnetic field dynamics, and/or signal modulation.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

For many applications magnetic fields of interest are small perturbations relative to some applied bias magnetic field. For these, optically-detected magnetic resonance (ODMR) peaks only move a small amount. For these applications, it is sufficient to monitor a single peak on the side of an ODMR peak and that signal will go up or down in response to the ODMR peak shifting in frequency (which is the natural response of nitrogen-vacancy (NV) diamond to a change in magnetic field). The technical noise and diamond thermal drifts of the system can also cause the signal to go up and down and the separation of these phenomena are challenging.

However, if multiple points on the same or complimentary peaks are monitored and some math is applied, the signal of interest can be recovered while the noise can be nulled. In the simplest description, if one monitors frequencies on the left- and right-hand side of an ODMR peak, the “technical noise” (i.e., noise that can result from laser stability problems and is responsible for limiting the sensitivity well above the photon shot noise limit (PSNL)) will be fully correlated (when one goes up, the other does as well). The signal response to the magnetic field will be anticorrelated (when one goes up, the other goes down).

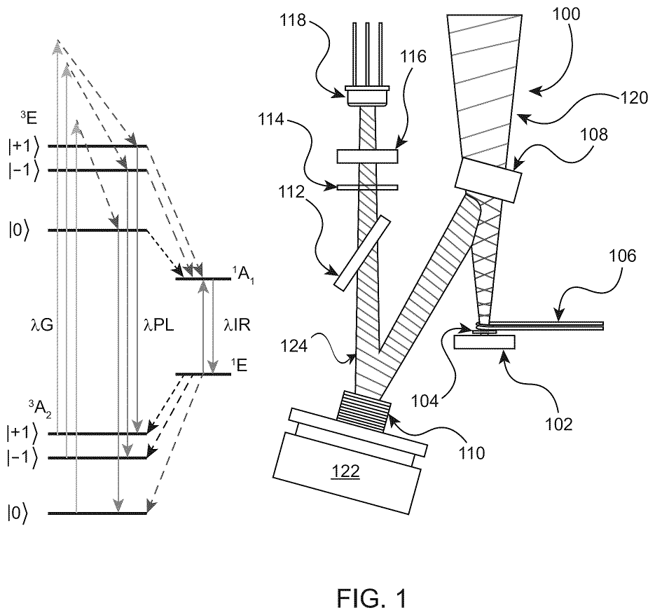

Referring to FIG. 1, a hybrid laser system 100 is shown. The hybrid laser system 100 includes a high reflectivity mirror 102 (which may be a double-coated high reflectivity mirror), a nitrogen-vacancy (NV) center diamond 104 (“NV center”), a microwave antenna 106, a dichroic mirror 108, a half-vertical cavity surface emitting laser (½ VCSEL) chip 110, a birefringent filter 112, an etalon 114, an output coupler 116, and a photodiode 118. A heat sink 122 may be mechanically and thermally coupled to the ½ VCSEL chip 110. The ½ VCSEL chip 110 may generate a beam 124. Light 120 may be pumped into the system 100 via the dichroic mirror 108, which may be concave. The light 120 pumped to the system 100 may be green light. For example, the light 120 may have a wavelength of 532 nm.

Referring to FIG. 1, continuous wave (CW) optically detected magnetic resonance (ODMR) can be understood by reviewing the energy diagram shown on the left side of FIG. 1. The NV center 104 may have a ground and excited electronic spin triplet state, ³A₂ and ³E, respectively, with the spin-conserving transition between the two having a zero-phonon line of 637 nm. In the ground triplet state, the spin 0 state is split from the spin±1 states by the zero-field splitting (ZFS) parameter, D≈2.87 GHz. Under the presence of a magnetic field, the degeneracy of the spin±1 states is lifted due to the Zeeman effect. These triplet states are coupled to two singlet states, ¹E and ¹A₁, by spin-dependent nonradiative intersystem crossings. The transition energy between the singlet excited and ground states can have, for example, a zero-phonon line of 1042 nm. Manipulation of the population in the ground triplet state by microwave fields may then result in magnetic field dependent absorption of, to continue with the example, 1042 nm light. The NV center energy structure is depicted in FIG. 1. The diamond sample used can be, for example, a 3 mm×3 mm×500 μm NV diamond plate grown with chemical vapor deposition. In some embodiments, the diamond plate can have a nitrogen vacancy density of 300 ppb and a spin dephasing time T₂* of 1 μs.

The diamond sample can be antireflection coated for light (e.g., 1042 nm light) using single layer of Al₂O₃. The laser threshold magnetometry (LTM) presented can be a VECSEL which utilized a half-vertical cavity surface emitting laser (½-VCSEL 110) gain chip. The ½-VCSEL can be processed from a wafer grown by metal organic chemical vapor deposition on a GaAs substrate. It can be composed of 12 compressively strained InGaAs quantum wells with GaAs barriers and a strain compensating GaAsP layer between each quantum well followed by 25 alternating pairs of AlGaAs/AlAs serving as a high reflectivity (Rs>99.9) distributed Bragg reflector (DBR). Thicknesses may be chosen to achieve resonant periodic gain. The DBR can be solder bonded to a poly-crystalline diamond plate, which may act as a heat spreader. The GaAs substrate can be removed by chemical wet etching exposing an optically flat air-semiconductor interface. The chip can be anti-reflection coated with a single layer of SiO2 or SiN by electron beam evaporation for the 808 nm pump laser light.

The chip can then be clamped to the heat sink 122 (e.g., a copper heat sink). Additionally, the VECSEL can be composed of a plane highly reflective (HR) mirror (HR mirror 102), a plane output coupler (OC 116), and a concave (e.g., 50 mm radius of curvature) dichroic mirror (DM 108). The cavity geometry can be chosen to achieve, for example, a tight focus (2 ws≈50 μm) of the TEM₀₀ mode in the diamond sample to limit the number of surface imperfections interacting with the lasing mode, and reduce the required power of the pump laser light (e.g., 532 nm pump laser light) used to spin polarize the NV centers. The DM can be coated to be HR for 1042 nm light (Rₛ>99.9%) and low reflectivity for 532 nm light (R_{g}<10%). The 532 nm pump laser can be coupled into the diamond colinear to the cavity mode through the DM and focused onto the diamond using a plano-convex 10 cm focal length lens to achieve an approximate 2 wg≈70 μm spot diameter at the NV-doped diamond sample. The plane mirror can be directly behind the diamond and can be coated to be HR for multiple wavelengths of light (e.g., both 1042 nm light and 532 nm light (Rₛ=R_{g}>99.9%). This may result in a double pass of some light (e.g., 532 nm pump light) in the diamond and can result in a further reduction in the pump power required to achieve a similar degree of spin polarization.

Furthermore, this geometry may spatially separate the lasing mode, which is outcoupled through the OC (Rₛ≈99%) from the unused pump light (e.g., 532 nm pump light) and NV photoluminescence. The cavity geometry can also result in an output beam collimated well enough (z_{R}≈12 cm) for efficient collection without the need for additional optics.

To further limit stray light from reaching the detector an iris can be placed between the output coupler and a low noise InGaAs photodiode (PD), and the distance between the iris and PD can be covered to limit the angular extent of the collected light. The ½-VCSEL chip can be pumped with light (e.g., 808 nm light) by a fiber coupled laser diode and the chips gain may peak (e.g., around 1040 nm). A birefringent filter (BRF) can be used to tune the lasing modes to a given wavelength (e.g., 1042 nm) and an etalon (e.g., a YAG etalon) can be used to achieve single-frequency operation. A loop MW antenna can be placed inside the VCSEL about 1 mm from the surface of the diamond sample. The MW antenna can be aligned such that both the cavity mode (e.g., 1042 nm cavity mode) and pump light (e.g., 532 nm pump light) pass through the center of the loop. The entire laser can be built on a single CNC machined aluminum plate to improve the stability of the cavity by limiting random acoustic vibrations.

Two identical permanent ring magnets or electromagnets can be placed near the diamond to lift a degeneracy of the four NV center orientations. After fine adjustments to the position of these magnets, the transition frequencies of these four orientations can be fully non-degenerate and approximately evenly spaced. To perform this calibration, a single amplitude modulated microwave tone (e.g., from a Stanford Research Systems SG 386 signal generator amplified by a Mini-Circuits ZHL-5W-63-S+ amplifier) can be swept across the relevant frequency range. The resulting photocurrent can then be analyzed by a lock-in amplifier (LIA) (e.g., a Stanford Research Systems SR830 LIA).

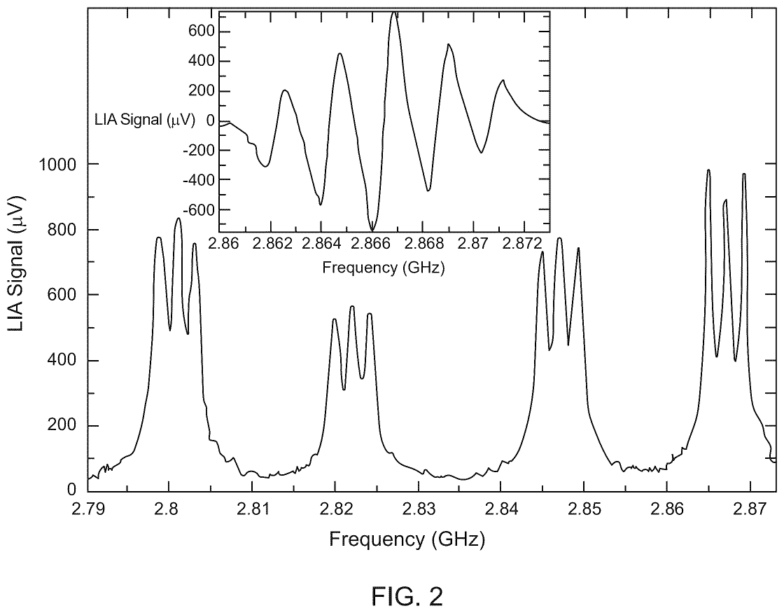

In FIG. 2 the transitions corresponding to mₛ=0→mₛ=+1 are shown. Within each transition, three distinct resonances are observed corresponding to the hyperfine interaction of the electron and ¹⁴N nucleus. In CW-ODMR, complex microwave probes may be used for improved performance. To achieve better sensitivities, a three-tone frequency modulated microwave probe can be used instead of a single-amplitude modulated probe used to capture the ODMR spectrum. This scheme may enable all three hyperfine features of a given transition to be simultaneously probed. Signals can be generated by mixing a frequency modulated output of a signal generator with an output of an arbitrary waveform generator (e.g., Agilent 33220A arbitrary waveform generator) set to the frequency of the axial hyperfine constant (e.g., 2.158 MHz) in a double balanced mixer (e.g., ZFM-4212+, Mini Circuits). A 10 dB coupler (e.g., MC-2104-10, Fairview) in combination with a digital step attenuator (e.g., ZX76-15RA-PNS+, Mini Circuits) and two-way power splitter (e.g., ZX10-2-42-S+, Mini Circuits) can be used to balance amplitudes of the three tones. An in-phase signal detected by the LIA while sweeping this probe is shown in the inset plot of FIG. 2 for one of the transitions. Degeneracy of four nitrogen vacancy orientations may be lifted with two permanent ring magnets as described herein. The position of these magnets can be adjusted to provide an approximately even splitting of the transition lines. The inset plot of FIG. 2 shows the ODMR signal generated using a three-tone frequency modulated probe.

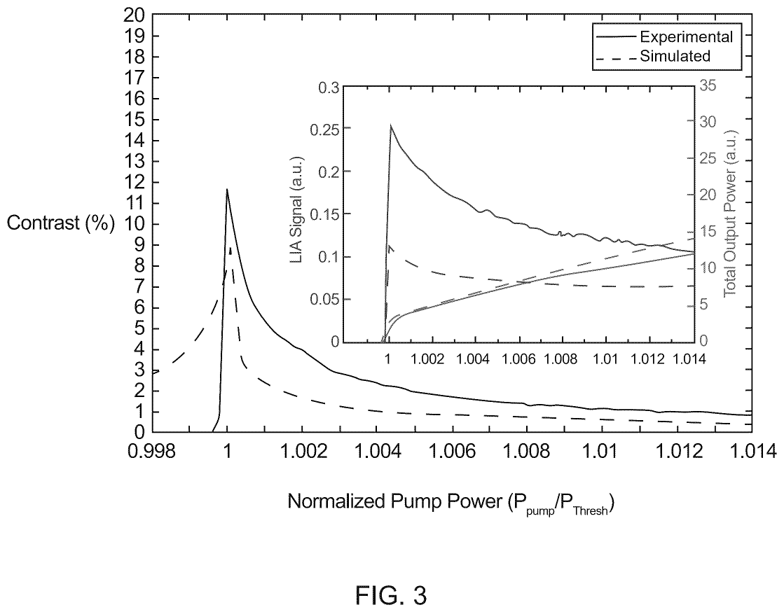

One predicted benefit of LTM is a contrast of the ODMR signal should increase as the laser approaches threshold, improving the projected PSNL sensitivity. To characterize the behavior of the contrast, a similar cavity to the one described above can be used; however, no permanent magnets may be applied and a Rₛ=99.6% reflectivity output coupler can be used. The contrast can be measured at the ZFS frequency with an amplitude modulated microwave probe (e.g., 1 kHz modulation, 21 dBm delivered to the antenna) by simultaneously measuring the total voltage across a 5 kΩ resistor with an HP 34401 digital multimeter (DMM) and the voltage due to the ODMR signal with the LIA (100 ms time constant, 24 dB/oct filter slope) connected in parallel. For this measurement, the diamond can be illuminated with 500 mW (13 kW/cm²) of 532 nm laser light. The ratio of the two measured values is reported as the contrast in FIG. 3 as a function of, for example, an 808 nm pump power. Additionally, the ODMR signal and the total voltages are reported in the inset plot of FIG. 3. Though the contrast does improve close to threshold, the behavior of the VCSEL near threshold diverges from that predicted by establish theory of infrared LTM. The LIA signal may be observed to decrease above threshold, which was a direct result of the nonlinear slope near threshold as shown in the inset of FIG. 3. This nonlinearity may behave like a saturable absorber, which can increase the signal near threshold and return it to a linear relationship at a few percent above threshold. This behavior may be simulated with an additional small saturable absorption term modifying the VCSEL photon lifetime, which may result in a nonlinear power above threshold. This saturable absorption effect may not be attributable to a particular element in the cavity, but effects like this could result from non-uniform pumping of the multi-quantum well gain chip. The simulated behavior may diverge from measurement below threshold due to the inclusion of spontaneous emission from the ½-VCSEL gain chip into the lasing mode. This may result in an exponential decay of the contrast below threshold; however, the photocurrent generated by the miniscule spontaneous emission reaching the detector may be likely below the noise floor of the photodiode.

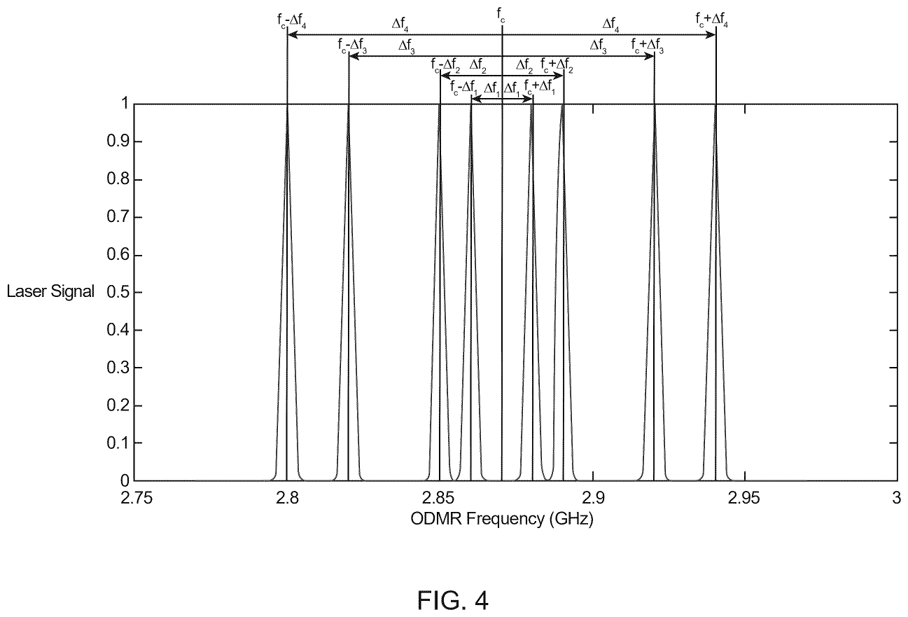

Referring to FIG. 4, and realizing that NV centers in diamond have an energy spectrum like on the left side of FIG. 1, IR absorption within the diamond depends on the ¹A₁ to ¹E state population difference. When pumping with an RF signal near a resonance (e.g. f_{c}−Δf₄ on the right of FIG. 4), the diamond absorption can drop, which both decreases the laser threshold and increases the laser slope, thus increasing laser output.

In some embodiments, different edges of a single ODMR “peak” are simultaneously monitored (FIG. 4) in the ODMR spectrum of NV diamond. Each pair of peaks correspond to the projection of the sensed magnetic field by an NV center aligned with a particular orientation of the diamond crystal structure. These peaks shift in frequency as the magnitude of that projected magnetic field changes. However, noises relating to laser stability and other experimental challenges will cause the total signal to rise and fall (the peak magnitude of the peak to go up and down). Typical ODMR readout monitors a single frequency on the rising- or falling-edge of an ODMR peak. As the magnetic field increases or decreases, the peak center will get closer or farther away from the monitor single frequency and the signal will go up or down. However, monitoring a single frequency will make it impossible to discern a signal change resulting from a fluctuation in magnetic field from a fluctuation in laser stability. By monitoring two frequencies—one on each side of the ODMR peak which, together, will provide the ability to distinguish between fluctuation due to changes in magnetic field and fluctuations due to noise.

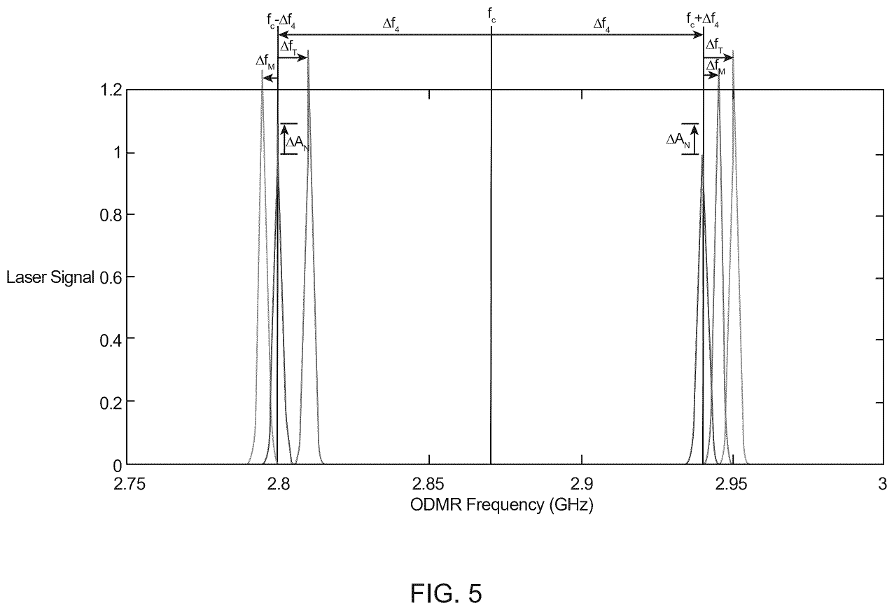

In this scheme, magnetic fields will shift each center frequency (e.g., f_{c}−Δf₄) proportional to the magnetic field component along the direction of that NV dipole, and shift it left or right, while it's complementary pair (e.g., f_{c}+Δf₄) will shift right or left, respectively. Temperature changes in the diamond will shift f_{c}+, so that the complementary pair shift in tandem (both left or both right). Mechanical/thermal laser noise will shift the amplitudes of all peaks up and down in tandem. FIG. 5 demonstrates these changes along one NV dipole projection.

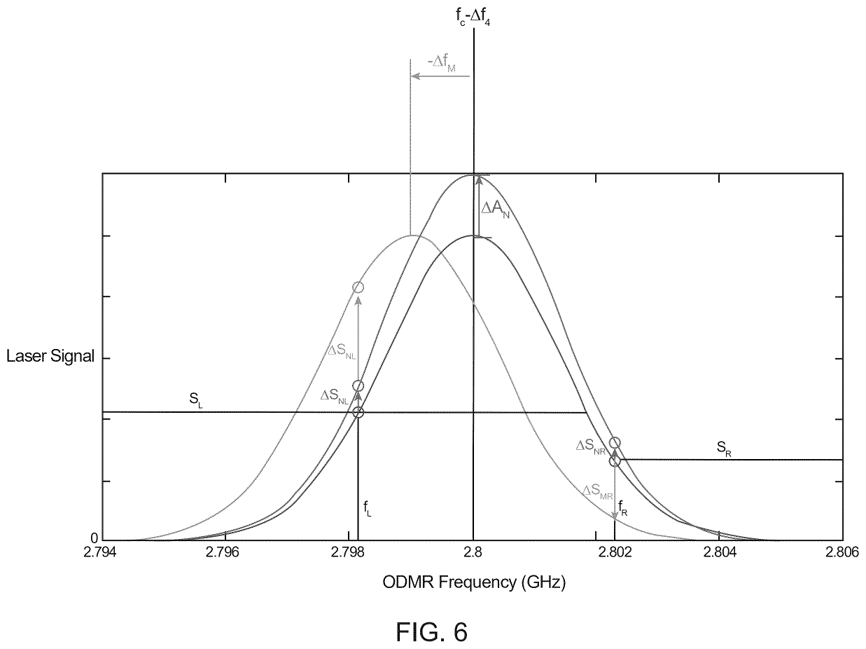

Referring to FIG. 6, looking at a single ODMR frequency (e.g. f_{L}), it can be seen that there is a laser signal with no perturbation (S_{L}). As the signal is perturbed, this signal gets modified. Consider that Laser Noise is referred to as ΔS_{NL} and the magnetic field as ΔS_{ML}, the net signal at frequency f_{L} is S_{L}+ΔS_{NL}+ΔS_{ML}. Looking at the right side of the signal gives similar results: Looking at a single ODMR frequency (e.g. f_{R}), it can be seen that there is a laser signal with no perturbation (S_{R}). As the signal is perturbed, this signal gets modified as follows: laser noise: ΔS_{NR}, magnetic field: ΔS_{MR}. The net signal at frequency f_{R} is S_{R}+ΔS_{NR}+ΔS_{MR}. The signals of interest here are ΔS_{ML} and ΔS_{MR}. Accordingly, if the two signals are subtracted from one another:

$$\begin{matrix}{S}_{SUM} = {S}_{L} + Δ {S}_{NL} + Δ {S}_{ML} - {S}_{R} + Δ {S}_{NR} - Δ {S}_{MR} \\ = ( {S}_{L} - {S}_{R} ) + ( Δ {S}_{NL} - Δ {S}_{NR} ) + ( Δ {S}_{ML} - Δ {S}_{MR} )\end{matrix}$$

But ΔS_{ML} and ΔS_{MR} have opposing signs, so:

$${S}_{SUM} = ( {S}_{L} - {S}_{R} ) + ( Δ {S}_{NL} - Δ {S}_{N R} ) + \vert Δ {S}_{ML} \vert + \vert Δ {S}_{MR} \vert$$

Said another way, if one subtracts the signal on the right-hand side from the signal on the left-hand side of peak, the noises will subtract while the signals will add.

Further, if one normalizes the left-hand and right-hand side signals and then subtracts them from each other and realizes the technical noise is expected to be proportional and constant across frequencies, the noise and the bias signals will cancel out and all that remains in the response to the magnetic field.

$$\begin{matrix}{S}_{sum}^{( N )} = \frac{{S}_{L} + Δ {S}_{NL} + Δ {S}_{ML}}{{S}_{L}} - \frac{{S}_{R} + Δ {S}_{NR} - Δ {S}_{MR}}{{S}_{R}} \\ = ( \frac{Δ {S}_{NL}}{{S}_{L}} - \frac{Δ {S}_{NR}}{{S}_{R}} ) + ( \frac{Δ {S}_{NL}}{{S}_{L}} - \frac{Δ {S}_{NR}}{{S}_{R}} )\end{matrix}$$

Moreover, in this case, the signals should be highly correlated and therefore the noises should increase/decrease proportionally (based on multiplicative adding). As such:

$$\frac{Δ {S}_{NL}}{{S}_{L}} = \frac{Δ {S}_{NR}}{{S}_{R}}$$

The normalized sum simplifies dramatically, where noise scaling terms disappear completely:

$${S}_{sum}^{( N )} = ( \frac{Δ {S}_{ML}}{{S}_{L}} - \frac{Δ {S}_{MR}}{{S}_{R}} )$$

On the other hand, if each signal is not normalized but recordings are taken at equal distances from the center of each peak, S_{L} and S_{R} are the same and the ΔS_{NL} and ΔS_{NR} are also equivalent and the magnetic response (ΔS_{ML}=−ΔS_{MR}) are equal and opposite. That is, if one sits equidistant from the peak on the left-hand and right-hand side of the peak, normalization is unnecessary, and both noises and the bias signals will cancel out. So:

$${S}_{sum} = 2 Δ {S}_{ML}$$

Practically speaking, because the ODMR response of the NV diamond is proportional to the time-average power of the RF power, the general scheme for finding a signal at, for example, f_{L} is to modulate at a frequency much lower than f_{L} (in this case, in the single 10's of kHz) and use a lock-in amplifier to filter only that frequency. Because extracting the signals at two RF frequencies on either side of a single peak (e.g., f_{L} and f_{R}) is of interest, one technique to retrieve each of these signals is to modulate each frequency at a different low lock-in frequency (e.g. f_{mL} modulates the RF signal at f_{L} and f_{mR} modulates the signal at f_{R}) and use a separate lock-in amplifier to retrieve each signal. The retrieved f_{L} from f_{R} (or vice versa) can then be subtracted, where unwanted signals will cancel out, leaving magnetic field signals and thermal signals only. This can be used to at least partially suppress random intensity noise (RIN). This can also be used to normalize each peak, therefore completely suppressing RIN.

Because subtracting signals at f_{L} and f_{R} is of interest, this can be done with a single lock-in amplifier applying a signal modulation frequency f_{M} to f_{L} and f_{R}, while assuring the two signals are 180 deg out of phase with each other. On a single detector, these will automatically subtract and can be used to at least partially suppress RIN. If the average signals are the same (that is to say, f_{L} and f_{R} are equidistant from, but on opposite sides of a symmetric peak), this will completely suppress common channel noise and get rid of any RIN.

Like in the aforementioned technique of monitoring two frequencies on either side of a single peak, two peaks can be monitored with added benefits. Because the ODMR signals generate two peaks on either side of an average, two different peaks on the (either low-frequency or high-frequency) side can be monitored. This will have all the benefits of incarnation (1) above but also suppress thermal drifts in the diamond. Because extracting the signals at two RF frequencies on one side of two peaks making up a pair (e.g., f_{L} and f_{R}) is of interest, each of these signals can be retrieved by modulating each frequency at a different low lock-in frequency (e.g., f_{mL} modulates the RF signal at f_{L} and f_{mR} modulates the signal at f_{R}) and use a separate lock-in amplifier to retrieve each signal. The retrieved f_{L} from f_{R} (or vice versa) is then subtracted. This can be used to at least partially suppress RIN and thermal drifts. This can also be used to normalize each peak, therefore completely suppressing RIN and thermal drifts.

Like above, two peaks of a pair at the same frequency can be monitored, but 180-deg out of phase. On a single detector, these will automatically subtract and can be used to at least partially suppress RIN and thermal drifts. If the average signals are the same (that is to say, f_{L} and f_{R} are equidistant from and on the same side of a peak pair, this will completely suppress common channel noise, RIN, and thermal drifts.

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A method of accounting for signal noise in a hybrid laser system that includes a high reflectivity mirror, a nitrogen-vacancy center diamond, a microwave antenna, a dichroic mirror, a half-vertical cavity surface emitting laser (VCSEL), a birefringent filter, an etalon, an output coupler, and a photodiode, the method comprising:
measuring a shift in a left-hand side frequency as related to an optically detected magnetic resonance (ODMR) frequency peak of an ODMR signal;
measuring a shift in a right-hand side frequency as related to the ODMR frequency peak;
normalizing the shift in the left-hand side frequency;
normalizing the shift in the right-hand side frequency;
comparing the shift in the left-hand side frequency to the shift in the right-hand side frequency to determine a technical noise associated with the ODMR signal.

2. A method of retrieving signals at two radiofrequencies on either side of a peak frequency comprising:
modulate a left-hand side frequency at a left-hand low lock-in modulation frequency and retrieve the modulated left-hand side frequency using a first lock-in amplifier;
modulate a right-hand side frequency at a right-hand low lock-in modulation frequency and retrieve the modulated right-hand side frequency using a second lock-in amplifier;
subtract the modulated left-hand side frequency from the right-hand side frequency using a single lock-in amplifier using a signal modulation frequency to the left-hand side frequency and the right-hand side frequency based on the left-hand side frequency and the right-hand side frequency being 180 degrees out of phase as compared to one another.

3. A method of suppressing noise and accounting for thermal drift in a hybrid laser system, the method comprising:
monitoring a first frequency peak and a second frequency peak on either of: 1) a low-frequency side or, 2) a high-frequency side of an average frequency peak;
modulating the first frequency peak at a first low lock-in frequency and retrieve the modulated first frequency peak with a first lock-in amplifier;
modulating the second frequency peak at a second low lock-in frequency and retrieve the modulated second frequency peak with a second lock-in amplifier;
subtracting the modulated, retrieved second frequency peak from the modulated, retrieved first frequency peak to account for thermal drift in the hybrid laser system.
